(19) United States
(12) Patent Application Publication
(10) Pub. No.: US 2024/0043606 A1
(43) Pub. Date: Feb. 8, 2024

(54) POLYHYDRIC HYDROXY RESIN, EPOXY RESIN, AND THEIR PRODUCTION METHODS, AND EPOXY RESIN COMPOSITION AND CURED PRODUCT THEREOF

(71) Applicant: NIPPON STEEL Chemical & Material Co., Ltd., Tokyo (JP)

(72) Inventors: Masahiro SOH, Tokyo (JP); Takayuki SAITOH, Tokyo (JP); Kazuo ISHIHARA, Tokyo (JP)

(73) Assignee: NIPPON STEEL Chemical & Material Co., Ltd., Tokyo (JP)

(21) Appl. No.: 18/265,258

(22) PCT Filed: Dec. 6, 2021
(86) PCT No.: PCT/JP2021/044646

§ 371 Date: Jun. 5, 2023

(30) Foreign Application Priority Data
Dec. 7, 2020 (JP) 2020-202784

(51) Int. Cl. C08G 59/06; C08G 61/12; C08G 59/62

(52) U.S. Cl. CPC C08G 59/063; C08G 61/12; C08G 59/621

(57) ABSTRACT

To provide an epoxy resin composition exhibiting excellent low-dielectric properties, a polyvalent hydroxy resin and an epoxy resin that each provide such an epoxy resin composition, and a method for producing such a resin. A polyvalent hydroxy resin represented by the following general formula (1).

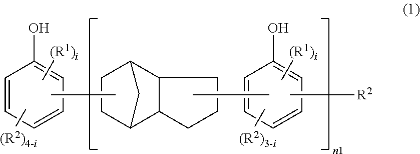

### TECHNICAL FIELD

The present invention relates to a polyvalent hydroxy resin or an epoxy resin excellent in low-viscosity properties and low-dielectric properties, and a method for producing such a resin.

### BACKGROUND ART

Epoxy resins are excellent in adhesiveness, flexibility, heat resistance, chemical resistance, insulation properties and curing reactivity, and thus are used variously in paints, civil adhesion, cast molding, electrical and electronic materials, film materials, and the like. In particular, epoxy resins, to which flame retardance is imparted, are widely used in applications of printed-wiring substrates as one of electrical and electronic materials.

In recent years, information equipment has been rapidly progressively reduced in size and increased in performance, and materials for use in the fields of semiconductors and electronic components have been accordingly demanded to have higher performance than even before. In particular, epoxy resin compositions serving as materials for electrical and electronic components have been demanded to have low-dielectric properties along with thinning and functionalization of substrates.

Dicyclopentadiene phenol resins and the like having aliphatic backbones introduced, which have been heretofore used for reduction in permittivity in applications of laminated boards, are less effective for improvement in dielectric tangent and have no satisfiable low-viscosity properties for increase in amount of filling materials (Patent Literatures 1 and 2). While improvement in dielectric properties has been tried by use of aromatic-modified dicyclopentadiene phenol resins, both low-dielectric properties and low-viscosity properties have not been satisfied (Patent Literature 3).

### CITATION LIST

### Patent Literatures

Patent Literature 1: Japanese Patent Laid-Open No. 2001-240654
Patent Literature 2: Japanese Patent Laid-Open No. 5-339341
Patent Literature 3: Japanese Patent Laid-Open No. 2016-69524

### SUMMARY OF INVENTION

Accordingly, a problem to be solved by the present invention is to provide a polyvalent hydroxy resin and an epoxy resin thereof that each allow a cured product exhibiting an excellent dielectric tangent and also having favorable low-viscosity properties to be obtained, as well as an epoxy resin composition using such a resin and a method for producing such a resin.

In order to solve the above problem, the present inventors have made various studies, and as a result, have found that a dicyclopentadiene-type phenol resin can further react with an aromatic vinyl compound at a specified ratio to thereby allow an aromatic vinyl compound-derived aromatic backbone to be added to a phenol ring of the dicyclopentadiene-type phenol resin and furthermore an epoxy resin obtained by epoxidation of the phenol resin is excellent in low-viscosity properties and a cured product obtained by curing the epoxy resin with a curing agent is excellent in low-dielectric properties, thereby completing the present invention.

In other words, the present invention relates to a polyvalent hydroxy resin (A) represented by the following general formula (1):

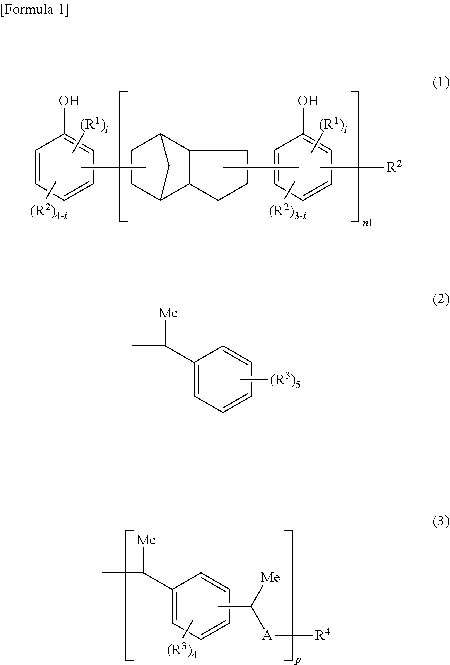

wherein each R¹ independently represents a hydrocarbon group having 1 to 8 carbon atoms, each R² independently represents a hydrogen atom, a group represented by formula (2), or a group represented by formula (3), and at least one R² is represented by formula (2) or formula (3); each R³ independently represents a hydrogen atom or a hydrocarbon group having 1 to 8 carbon atoms, and each R⁴ independently represents a hydrogen atom or a group represented by formula (2); A represents a residue obtained by removing two R² from the formula (1) and each R² here represents a hydrogen atom or a group represented by formula (2); Me represents a methyl group; i is an integer of 0 to 2; n1 represents the number of repetitions and an average value thereof is a number of 0 to 5; and p represents the number of repetitions and an average value thereof is a number of 0.01 to 3.
R¹ is preferably a methyl group or a phenyl group, and i is preferably 1 or 2.

The present invention relates to a method for producing a polyvalent hydroxy resin, including: reacting a polyvalent hydroxy resin (a) represented by the following general formula (4) and an aromatic vinyl compound (b) represented by the following general formula (5a) and/or general formula (5b):

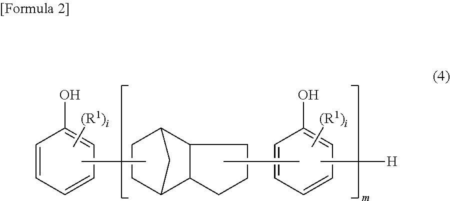

wherein each R¹ independently represents a hydrocarbon group having 1 to 8 carbon atoms; i is an integer of 0 to 2; and m represents the number of repetitions and an average value thereof is a number of 0 to 5;

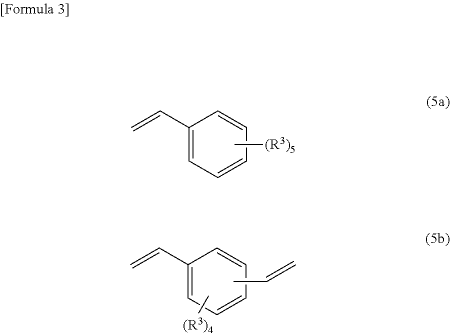

wherein each R³ represents a hydrogen atom or a hydrocarbon group having 1 to 8 carbon atoms.

The production method is preferably performed in the presence of an acid catalyst, and preferably, 0.05 to 2.0 mol of the aromatic vinyl compound per mol of a phenolic hydroxyl group of the polyvalent hydroxy resin is reacted at a reaction temperature of 50 to 200° C. in the presence of an acid catalyst.

The present invention relates to an epoxy resin represented by the following general formula (6):

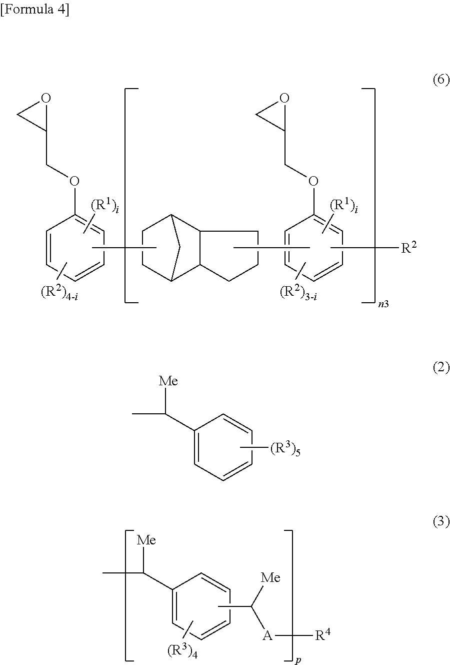

wherein each R¹ independently represents a hydrocarbon group having 1 to 8 carbon atoms, each R² independently represents a hydrogen atom, a group represented by formula (2), or a group represented by formula (3), and at least one R² is represented by formula (2) or formula (3); each R³ independently represents a hydrogen atom or a hydrocarbon group having 1 to 8 carbon atoms, and each R⁴ independently represents a hydrogen atom or a group represented by formula (2); A represents a residue obtained by removing two R² from the formula (6) and each R² here represents a hydrogen atom or a group represented by formula (2); Me represents a methyl group; i is an integer of 0 to 2; n3 represents the number of repetitions and an average value thereof is a number of 0 to 5; and p represents the number of repetitions and an average value thereof is a number of 0.01 to 3.

The present invention also relates to a method for producing the epoxy resin, including: reacting 1 to 20 mol of epihalohydrin per mol of a phenolic hydroxyl group of the above polyvalent hydroxy resin (A), in the presence of an alkali metal hydroxide.

The present invention also relates to an epoxy resin composition including an epoxy resin and a curing agent, wherein the above polyvalent hydroxy resin (A) and/or the epoxy resin are/is essential.

The present invention also relates to a cured product obtained by curing the epoxy resin composition, and a prepreg, a laminated board or a printed-wiring substrate using the epoxy resin composition.

The production method of the present invention can allow an aromatic vinyl compound-derived aromatic backbone to be easily added to a phenol ring of a dicyclopentadiene-type polyvalent hydroxy resin. A cured product using a polyvalent hydroxy resin and/or an epoxy resin obtained by the production method exhibits an excellent dielectric tangent, and furthermore an epoxy resin composition excellent in copper foil peel strength and interlayer cohesion strength in a printed-wiring board application is provided.

### BRIEF DESCRIPTION OF DRAWINGS

FIG. 1 A GPC chart of a phenol resin obtained in Example 1.

FIG. 2 A GPC chart of an epoxy resin obtained in Example 6.

### DESCRIPTION OF EMBODIMENTS

Hereinafter, embodiments of the present invention will be described in detail.

The polyvalent hydroxy resin of the present invention (also referred to as “phenol resin”) is a polyvalent hydroxy resin (A) represented by the general formula (1). The resin is obtained by, for example, reacting an aromatic vinyl compound (b) represented by general formula (5a) and/or general formula (5b) with the dicyclopentadiene-type polyvalent hydroxy resin (a) represented by the general formula (4), in the presence of a Lewis acid.

The polyvalent hydroxy resin (a) has a structure where a phenol compound is linked by dicyclopentadiene. The polyvalent hydroxy resin (A) of the present invention is the dicyclopentadiene-type polyvalent hydroxy resin (a), in which the aromatic backbone represented by the formula (2) is further added to a phenol ring.

In the general formula (1), R¹ preferably represents a hydrocarbon group having 1 to 8 carbon atoms, an alkyl group having 1 to 8 carbon atoms, an aryl group having 6 to 8 carbon atoms, an aralkyl group having 7 to 8 carbon atoms, or an allyl group. The alkyl group having 1 to 8 carbon atoms may be any of linear, branched and cyclic groups, and examples thereof include a methyl group, an ethyl group, a propyl group, an isopropyl group, a n-butyl group, a t-butyl group, a hexyl group, a cyclohexyl group and a methylcyclohexyl group, but not limited thereto. Examples of the aryl group having 6 to 8 carbon atoms include a phenyl group, a tolyl group, a xylyl group and an ethylphenyl group, but not limited thereto. Examples of the aralkyl group having 7 to 8 carbon atoms include a benzyl group and an α-methylbenzyl group, but not limited thereto. Among these substituents, a phenyl group and a methyl group are preferable and a methyl group is particularly preferable, from the viewpoints of availability, and reactivity of a cured product obtained. The position of substitution with R¹ may be any of the ortho-position, the meta-position and the para-position, and is preferably the ortho-position.

Each R² represents a hydrogen atom, or a group represented by formula (2) or formula (3), and at least one R² is represented by formula (2) or formula (3). Each R² does not necessarily represent only a substituent and represents a hydrogen atom, unlike R¹ as a substituent.

The group represented by the formula (2) corresponds to a monovinyl compound-derived group represented by general formula (5a), in the aromatic vinyl compound (b), and the group represented by the formula (3) corresponds to a divinyl compound-derived group represented by general formula (5b), in the aromatic vinyl compound (b).
i is the number of substituents R¹, and is 0 to 2, preferably 1 or 2, more preferably 2.
n1 is the number of repetitions and represents a number of 0 or more, and the average value (number average) thereof is 0 to 5, preferably 1.0 to 4.0, more preferably 1.1 to 3.0, further preferably 1.2 to 2.5.

In the formula (2), each R³ represents a hydrogen atom or a hydrocarbon group having 1 to 8 carbon atoms. Examples of the hydrocarbon group having 1 to 8 carbon atoms are the same as in R¹. Each R³ also does not necessarily represent only a substituent and represents a hydrogen atom as in R², unlike R¹ as a substituent.

When the monovinyl compound represented by the formula (5a) is used as a raw material, each R³ preferably represents a hydrogen atom, a methyl group, or an ethyl group, particularly preferably represents a hydrogen atom or an ethyl group, from the viewpoints of availability, and heat resistance of a cured product. When the divinyl compound represented by the formula (5b) is used as a raw material, each R³ may contain a vinyl group. The position of substitution in each R³ may be any of the ortho-position, the meta-position and the para-position, and is preferably any of the meta-position and the para-position.

Preferably, one R³ represents an ethyl group and the balance represents a hydrogen atom.

In the formula (3), A represents a residue obtained by removing two R² from the formula (1), and such two R² here represent a hydrogen atom or the group represented by the formula (2). In other words, A does not contain any group represented by the formula (3).

R³ in the formula (3) also has the same meaning as R³ in the formula (2).

Each R⁴ represents a hydrogen atom or the group represented by the formula (2). Each R⁴ also does not necessarily represent only a substituent and represents a hydrogen atom as in R² and R³, unlike R¹ as a substituent.
p is the number of repetitions and represents a number of 0 or more, and the average value (number average) thereof is 0.01 to 3, preferably 0.1 to 2.0, more preferably 0.2 to 1.0, further preferably 0.3 to 0.8.

The phenol resin of the present invention preferably has a weight average molecular weight (Mw) of 400 to 2000, more preferably 500 to 1500. The phenol resin preferably has a number average molecular weight (Mn) of 350 to 1500, more preferably 400 to 1000.

The phenolic hydroxyl group equivalent (g/eq.) is preferably 190 to 500, more preferably 200 to 500, further preferably 220 to 400.

The molecular weight distribution of the polyvalent hydroxy resin (a) as a raw material is kept almost as it is and the contents of an n1=0 form, an n1=1 form, and an n1≥2 form in the general formula (1), according to GPC, are preferably respectively in the ranges of 10% by area or less, 50 to 90% by area, and 0 to 50% by area.

The softening point is preferably 50 to 180° C., more preferably 50 to 120° C.

The phenol resin of the present invention exhibits low-viscosity properties, and has a melt viscosity at 150° C. of 0.01 to 1.0 Pa·s, preferably 0.03 to 0.5 Pa·s, more preferably 0.05 to 0.4 Pa·s.

In the general formula (4), R¹ and i have the same meanings as the respective definitions in the general formula (1), and m has the same meaning as n1 in the general formula (1).

In the general formula (5a), each R³ represents a hydrogen atom or a hydrocarbon group having 1 to 8 carbon atoms. Examples of the hydrocarbon group having 1 to 8 carbon atoms are the same as in R¹. Each R³ preferably represents a hydrogen atom, a methyl group, or an ethyl group, particularly preferably represents a hydrogen atom or an ethyl group, from the viewpoints of availability, and heat resistance of a cured product. The position of substitution in each R³ may be any of the ortho-position, the meta-position and the para-position, and is preferably any of the meta-position and the para-position.

In the general formula (5b), the position of substitution with a vinyl group may be any of the ortho-position, the meta-position and the para-position, and is preferably any of the meta-position and the para-position or may be a mixture thereof

The aromatic vinyl compound (b) represented by the general formula (5) essentially includes a monovinyl compound (the compound represented by the general formula (5a)), and may include a divinyl compound (the compound represented by the general formula (5b)). As the amount of compounding of the divinyl compound is larger, the molecular weight of the polyvalent hydroxy resin (A) is increased. Thus, the amount of compounding may be adjusted in consideration of the molecular weight of the polyvalent hydroxy resin (a) in order that an objective molecular weight is achieved. The monovinyl compound is the substituent R² or R⁴ represented by the formula (2) due to addition reaction, and exerts the effect of reducing dielectric properties.

Examples of the monovinyl compound include vinyl aromatic compounds such as styrene, vinylnaphthalene, vinyl biphenyl, and α-methylstyrene; nuclear alkyl-substituted vinyl aromatic compounds such as o-methylstyrene, m-methylstyrene, p-methylstyrene, o,p-dimethylstyrene, o-ethylvinylbenzene, m-ethylvinylbenzene, p-ethylvinylbenzene, ethyl vinyl biphenyl, and ethylvinylnaphthalene; and cyclic vinyl aromatic compounds such as indene, acenaphthylene, benzothiophene, and coumarone. Preferred are styrene and ethylvinylbenzene.

These can be used singly or in combinations of two or more kinds thereof.

Examples of the divinyl compound include divinyl aromatic compounds such as divinylbenzene, divinylnaphthalene, and divinyl biphenyl. Preferred is divinylbenzene.

These can be used singly or in combinations of two or more kinds thereof.

The amounts of compounding of the monovinyl compound and the divinyl compound may be respectively 15 to 50% by mass and 50 to 85% by mass based on the entire amount of the vinyl compound. The amount of compounding of the monovinyl compound is preferably 30 to 50% by mass, more preferably 40 to 50% by mass. The amount of compounding of the divinyl compound is preferably 50 to 70% by mass, more preferably 50 to 60% by mass.

The polyvalent hydroxy resin (a) is obtained by reacting a phenol compound represented by the following general formula (7) with dicyclopentadiene in the presence of a Lewis acid:

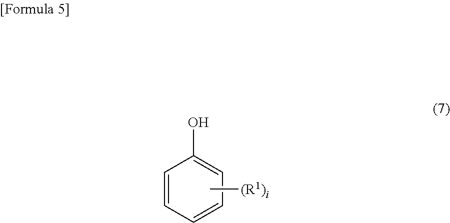

wherein R¹ and i have the same meanings as the respective definitions in the general formula (1).

The phenolic hydroxyl group equivalent (g/eq.) in the polyvalent hydroxy resin (a) is preferably 160 to 220, more preferably 165 to 210, further preferably 170 to 200.

The contents of an m=0 form, an m=1 form, and an m≥2 form, according to GPC, are preferably respectively in the ranges of 10% by area or less, 50 to 90% by area, and 0 to 50% by area.

Examples of the phenol compound represented by the general formula (7) include phenol, cresol, ethylphenol, propylphenol, isopropylphenol, n-butylphenol, t-butylphenol, hexylphenol, cyclohexylphenol, phenylphenol, tolylphenol, benzylphenol, α-methylbenzylphenol, allylphenol, dimethylphenol, diethylphenol, dipropylphenol, diisopropylphenol, di(n-butyl)phenol, di(t-butyl)phenol, dihexylphenol, dicyclohexylphenol, diphenylphenol, ditolylphenol, dibenzylphenol, bis(α-methylbenzyl)phenol, methylethylphenol, methylpropylphenol, methylisopropylphenol, methylbutylphenol, methyl-t-butylphenol, methyl allylphenol and tolylphenylphenol. Phenol, cresol, phenylphenol, dimethylphenol, and diphenylphenol are preferable, and cresol and dimethylphenol are particularly preferable, from the viewpoints of availability, and reactivity of a cured product obtained.

The catalyst for use in the reaction is a Lewis acid, is specifically, for example, boron trifluoride, a boron trifluoride/phenol complex, a boron trifluoride/ether complex, aluminum chloride, tin chloride, zinc chloride or iron chloride, and in particular, a boron trifluoride/ether complex is preferable in terms of ease of handling. In the case of a boron trifluoride/ether complex, the amount of the catalyst used is 0.001 to 20 parts by mass, preferably 0.5 to 10 parts by mass based on 100 parts by mass of the dicyclopentadiene.

The ratio between the phenol compound and dicyclopentadiene in the reaction, as the ratio of dicyclopentadiene per mol of the phenol compound, is 0.08 to 0.80 mol, preferably 0.09 to 0.60 mol, more preferably 0.10 to 0.50 mol, further preferably 0.10 to 0.40 mol, particularly preferably 0.10 to 0.20 mol.

The reaction is favorably made in a manner where the phenol compound and a catalyst are loaded into a reactor and dicyclopentadiene is dropped over 0.1 to 10 hours, preferably 0.5 to 8 hours, more preferably 1 to 6 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide.

Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus the objective dicyclopentadiene phenol resin represented by the general formula (3) can be obtained. Preferably, the dicyclopentadiene is reacted in the entire amount as much as possible and the unreacted raw material phenol compound is recovered under reduced pressure.

During the reaction, a solvent, for example, an aromatic hydrocarbon compound such as benzene, toluene or xylene, a ketone compound such as methyl ethyl ketone or methyl isobutyl ketone, a halogenated hydrocarbon compound such as chlorobenzene or dichlorobenzene, or an ether compound such as ethylene glycol dimethyl ether or diethylene glycol dimethyl ether may be, if necessary, used.

The reaction method for introducing the aromatic backbone structure of the formula (2) or formula (3) into the polyvalent hydroxy resin (a) is a method for reacting the aromatic vinyl compound (b) with the polyvalent hydroxy resin (a) at a predetermined ratio. The reaction ratio of the aromatic vinyl compound (b) per mol of the phenolic hydroxyl group of the polyvalent hydroxy resin (a) is 0.05 to 2.0 mol, more preferably 0.1 to 1.0 mol, further preferably 0.15 to 0.80 mol, particularly preferably 0.30 to 0.70 mol.

The catalyst for use in the reaction is an acid catalyst, and specific examples thereof include mineral acids such as hydrochloric acid, sulfuric acid, and phosphoric acid, organic acids such as formic acid, oxalic acid, trifluoroacetic acid, and p-toluenesulfonic acid, Lewis acids such as zinc chloride, aluminum chloride, iron chloride, and boron trifluoride, and solid acids such as activated white earth, silica-alumina, and zeolite. In particular, p-toluenesulfonic acid is preferable in terms of ease of handling. In the case of p-toluenesulfonic acid, the amount of the catalyst used is 0.001 to 20 parts by mass, preferably 0.5 to 10 parts by mass based on 100 parts by mass of the polyvalent hydroxy resin (a).

The reaction is favorably made in a manner where the polyvalent hydroxy resin (a), the catalyst and a solvent are loaded into a reactor and dissolved, and then the aromatic vinyl compound (b) is dropped over 0.1 to 10 hours, preferably 0.5 to 8 hours, more preferably 0.5 to 5 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide. Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus an objective phenol resin can be obtained.

Examples of the solvent used in the reaction include solvents, for example, aromatic hydrocarbon compounds such as benzene, toluene and xylene, ketone compounds such as methyl ethyl ketone and methyl isobutyl ketone, halogenated hydrocarbon compounds such as chlorobenzene and dichlorobenzene, and ether compounds such as ethylene glycol dimethyl ether and diethylene glycol dimethyl ether. Such solvents may be used singly or as a mixture of two or more kinds thereof.

The epoxy resin of the present invention is represented by the general formula (6). The epoxy resin is obtained by a reaction of epihalohydrin such as epichlorohydrin with the polyvalent hydroxy resin (A) of the present invention. The reaction is performed according to a conventionally known method.

In the general formula (6), R¹, R², and i have the same meanings as the respective definitions in the general formula (1), and n3 has the same meaning as n1 in the general formula (1).

The epoxidation method can be made by, for example, addition of an alkali metal hydroxide such as sodium hydroxide in the form of a solid or an aqueous concentrated solution to a mixture of the phenol resin and an excess mole of epihalohydrin relative to the hydroxyl group of the phenol resin and a reaction at a reaction temperature of 30 to 120° C. for 0.5 to 10 hours, or addition of a quaternary ammonium salt such as tetraethylammonium chloride as a catalyst to the phenol resin and an excess mole of epihalohydrin, addition of an alkali metal hydroxide such as sodium hydroxide as a solid or an aqueous concentrated solution to polyhalohydrin ether obtained from a reaction at a temperature of 50 to 150° C. for 1 to 5 hours, and a reaction at a temperature of 30 to 120° C. for 1 to 10 hours.

The amount of epihalohydrin used in the reaction, relative to the hydroxyl group of the phenol resin, is 1 to 20-fold moles, preferably 2 to 8-fold moles. The amount of the alkali metal hydroxide used, relative to the hydroxyl group of the phenol resin, is 0.85 to 1.15-fold moles.

The epoxy resin obtained by such a reaction includes the unreacted epihalohydrin and alkali metal halide, thus the unreacted epihalohydrin is evaporated and removed and furthermore the alkali metal halide is removed by method(s) such as extraction with water and/or separation by filtration, from the reaction mixture, and thus an objective epoxy resin can be obtained.

The epoxy equivalent (g/eq.) of the epoxy resin of the present invention is preferably 200 to 4000, more preferably 220 to 2000, further preferably 250 to 700. In particular, when dicyandiamide is used as a curing agent, the epoxy equivalent is preferably 300 or more in order to prevent a dicyandiamide crystal from being precipitated on a prepreg.

The molecular weight distributions of the polyvalent hydroxy resin (a) and the phenol resin as raw materials are kept almost as they are and the contents of an n3=0 form, an n3=1 form, and an n3≥2 form in the general formula (6), according to GPC, are preferably respectively in the ranges of 10% by area or less, 40 to 90% by area, and 0 to 60% by area.

The total content of chlorine is preferably 2000 ppm or less, further preferably 1500 ppm or less.

The epoxy resin of the present invention exhibits low-viscosity properties, and has a melt viscosity at 150° C. of 0.01 to 1.0 Pa·s, preferably 0.05 to 0.7 Pa·s, more preferably 0.1 to 0.5 Pa·s.

The epoxy resin composition of the present invention can be obtained by use of the polyvalent hydroxy resin of the present invention and/or the epoxy resin of the present invention. The epoxy resin composition of the present invention includes the epoxy resin and a curing agent as essential components. In this aspect, the curing agent is partially or fully the polyvalent hydroxy resin of the present invention and the epoxy resin is partially or fully the epoxy resin of the present invention, or the curing agent is partially or fully the polyvalent hydroxy resin of the present invention and the epoxy resin is partially or fully the epoxy resin of the present invention.

Preferably, at least 30% by mass of the curing agent is the polyvalent hydroxy resin of the present invention, or at least 30% by mass of the epoxy resin is the epoxy resin of the present invention. The respective proportions of the curing agent and the epoxy resin are more preferably 50% by mass or more, further preferably 70% by mass. If the proportions are less than such values, dielectric properties may be degraded.

In other words, when 30% by mass or more of the curing agent corresponds to the polyvalent hydroxy resin of the present invention, the epoxy resin is not required to be the epoxy resin of the present invention, and when the polyvalent hydroxy resin of the present invention occupies less than 30% by mass of the curing agent, 30% by mass or more of the epoxy resin essentially corresponds to the epoxy resin of the present invention.

Various epoxy resins may be, if necessary, used singly or in combinations of two or more kinds thereof for the epoxy resin used for providing the epoxy resin composition of the present invention.

Any common epoxy resin having two or more epoxy groups in its molecule can be used as the epoxy resin that can be used in combination. Examples include a bisphenol A-type epoxy resin, a bisphenol F-type epoxy resin, a bisphenol AF-type epoxy resin, a tetramethyl bisphenol F-type epoxy resin, a hydroquinone-type epoxy resin, a biphenyl-type epoxy resin, a stilbene-type epoxy resin, a bisphenol fluorene-type epoxy resin, a bisphenol S-type epoxy resin, a bisthio ether-type epoxy resin, a resorcinol-type epoxy resin, a biphenyl aralkylphenol-type epoxy resin, a naphthalene diol-type epoxy resin, a phenol novolac-type epoxy resin, an aromatic modified phenol novolac-type epoxy resin, a cresol novolac-type epoxy resin, a alkyl novolac-type epoxy resin, a bisphenol novolac-type epoxy resin, a binaphthol-type epoxy resin, a naphthol novolac-type epoxy resin, a β-naphthol aralkyl-type epoxy resin, a dinaphthol aralkyl-type epoxy resin, an α-naphthol aralkyl-type epoxy resin, a trifunctional epoxy resin such as a trisphenylmethane-type epoxy resin, a tetrafunctional epoxy resin such as a tetrakisphenylethane-type epoxy resin, a dicyclopentadiene-type epoxy resin other than that in the present invention, polyhydric alcohol polyglycidyl ether such as 1,4-butane diol diglycidyl ether, 1,6-hexane diol diglycidyl ether, glycerol polyglycidyl ether, trimethylolpropane polyglycidyl ether, trimethylolethane polyglycidyl ether and pentaerythritol polyglycidyl ether, an alkylene glycol-type epoxy resin such as propylene glycol diglycidyl ether, an aliphatic cyclic epoxy resin such as cyclohexane dimethanol diglycidyl ether, a glycidyl ester compound such as dimer acid polyglycidyl ester, a glycidylamine-type epoxy resin such as phenyldiglycidylamine, tolyldiglycidylamine diaminodiphenylmethane tetraglycidylamine and an aminophenol-type epoxy resin, an alicyclic epoxy resin such as Celloxide 2021P (manufactured by Daicel Corporation), a phosphorus-containing epoxy resin, a bromine-containing epoxy resin, a urethane-modified epoxy resin, and an oxazolidone ring-containing epoxy resin, but not limited thereto. Such epoxy resins may be used singly or in combinations of two or more kinds thereof. An epoxy resin represented by the following general formula (8), a dicyclopentadiene-type epoxy resin other than that in the present invention, a naphthalene diol-type epoxy resin, a phenol novolac-type epoxy resin, an aromatic modified phenol novolac-type epoxy resin, a cresol novolac-type epoxy resin, an α-naphthol aralkyl-type epoxy resin, a dicyclopentadiene-type epoxy resin, a phosphorus-containing epoxy resin, and an oxazolidone ring-containing epoxy resin are further preferably used from the viewpoint of availability.

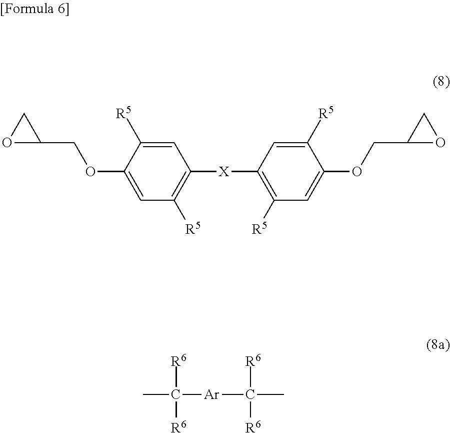

Each R⁵ independently represents a hydrocarbon group having 1 to 8 carbon atoms, and is, for example, an alkyl group such as a methyl group, an ethyl group, a n-propyl group, an isopropyl group, a n-butyl group, a t-butyl group, a n-hexyl group or a cyclohexyl group, and these may be the same as or different from each other.

X represents a divalent organic group, and represents, for example, an alkylene group such as a methylene group, an ethylene group, an isopropylene group, an isobutylene group or a hexafluoroisopropylidene group, —CO—, —O—, —S—, —SO₂—, —S—S—, or an aralkylene group represented by formula (8a).

Each R⁶ independently represents a hydrogen atom or a hydrocarbon group having one or more carbon atoms, for example, a methyl group, and these may be the same as or different from each other.

Ar represents a benzene ring or a naphthalene ring, and such a benzene ring or naphthalene ring may have an alkyl group having 1 to 10 carbon atoms, an alkoxy group having 1 to 10 carbon atoms, an aryl group having 6 to 11 carbon atoms, an aralkyl group having 7 to 12 carbon atoms, an aryloxy group having 6 to 11 carbon atoms or an aralkyloxy group having 7 to 12 carbon atoms, as a substituent.

A curing agent usually used, such as a phenol resin compound, an acid anhydride compound, an amine compound, a cyanate ester compound, an active ester compound, a hydrazide compound, an acidic polyester compound or an aromatic cyanate compound, can be, if necessary, used in addition to the polyvalent hydroxy resin (A) of the general formula (1), as the curing agent, singly or in combinations of two or more kinds thereof. When such a curing agent is used in combination, the proportion of such a curing agent used in combination in the entire curing agent is preferably 70% by mass or less, more preferably 50% by mass or less. If the proportion of such a curing agent used in combination is too high, the epoxy resin composition may have degraded dielectric properties.

The molar ratio of the active hydrogen group of the curing agent per mol of the epoxy group in the entire epoxy resin, in the epoxy resin composition of the present invention, is preferably 0.2 to 1.5 mol, more preferably 0.3 to 1.4 mol, further preferably 0.5 to 1.3 mol, particularly preferably 0.8 to 1.2 mol. If the molar ratio does not fall within such a range, curing is incomplete and no favorable physical properties of a cured product may be obtained. For example, when a phenol resin-based curing agent or an amine-based curing agent is used, the active hydrogen group and the epoxy group are compounded in almost equimolar amounts. When an acid anhydride-based curing agent is used, the number of moles of the acid anhydride group compounded per mol of the epoxy group is 0.5 to 1.2 mol, preferably 0.6 to 1.0 mol. When the phenol resin of the present invention is singly used as a curing agent, the phenol resin is desirably used in the range from 0.9 to 1.1 mol per mol of the epoxy resin.

The active hydrogen group mentioned in the present invention means a functional group having active hydrogen reactive with an epoxy group (encompassing a functional group having potentially active hydrogen which generates active hydrogen by hydrolysis or the like, and a functional group exhibiting equivalent curing action.), and specific examples include an acid anhydride group, a carboxyl group, an amino group and a phenolic hydroxyl group. Herein, 1 mol of a carboxyl group or a phenolic hydroxyl group is considered to correspond to 1 mol of the active hydrogen group and 1 mol of an amino group (NH₂) is considered to correspond to 2 mol of the active hydrogen group. When the active hydrogen group is not clear, the active hydrogen equivalent can be determined by measurement. For example, the active hydrogen equivalent of a curing agent used can be determined by a reaction of a monoepoxy resin having a known epoxy equivalent, such as phenyl glycidyl ether, and a curing agent having an unknown active hydrogen equivalent and then measurement of the amount of the monoepoxy resin consumed.

Specific examples of the phenol resin-based curing agent that can be used in the epoxy resin composition of the present invention include phenol compounds mentioned as so-called novolac phenol resins, for example, bisphenol compounds such as bisphenol A, bisphenol F, bisphenol C, bisphenol K, bisphenol Z, bisphenol S, tetramethyl bisphenol A, tetramethyl bisphenol F, tetramethyl bisphenol S, tetramethyl bisphenol Z, tetrabromobisphenol A, dihydroxydiphenylsulfide and 4,4′-thiobis(3-methyl-6-t-butylphenol), dihydroxybenzene compounds such as catechol, resorcin, methylresorcin, hydroquinone, monomethylhydroquinone, dimethylhydroquinone, trimethylhydroquinone, mono-t-butylhydroquinone and di-t-butylhydroquinone, hydroxynaphthalene compounds such as dihydroxynaphthalene, dihydroxymethylnaphthalene, dihydroxymethylnaphthalene and trihydroxynaphthalene, phosphorus-containing phenol curing agents such as LC-950PM60 (manufactured by Shin-AT&C Co., Ltd.), phenol novolac resins such as Shonol BRG-555 (manufactured by Aica Kogyo Co., Ltd.), cresol novolac resins such as DC-5 (manufactured by Nippon Steel Chemical & Material Co., Ltd.), triazine backbone-containing phenol resins, aromatic modified phenol novolac resins, bisphenol A novolac resins, trishydroxyphenylmethane-type novolac resins such as Resitop TPM-100 (manufactured by Gunei Chemical Industry Co., Ltd.), condensates of phenol compounds, naphthol compounds and/or bisphenol compounds with aldehyde compounds, such as naphthol novolac resins, condensates of phenol compounds, phenol compounds and/or naphthol compounds and/or bisphenol compounds with xylylene glycols, such as SN-160, SN-395 and SN-485 (manufactured by Nippon Steel Chemical & Material Co., Ltd.), condensates of phenol compounds and/or naphthol compounds with isopropenylacetophenones, reaction products of phenol compounds and/or naphthol compounds and/or bisphenol compounds with dicyclopentadienes, reaction products of phenol compounds and/or naphthol compounds and/or bisphenol compounds with divinylbenzenes, reaction products of phenol compounds and/or naphthol compounds and/or bisphenol compounds with terpene compounds, and condensates of phenol compounds and/or naphthol compounds and/or bisphenol compounds with biphenyl-based crosslinking agents, as well as polybutadiene-modified phenol resins and phenol resins having spiro rings. A phenol novolac resin, a dicyclopentadiene phenol resin, a trishydroxyphenylmethane-type novolac resin, an aromatic modified phenol novolac resin, and the like are preferable from the viewpoint of availability.

Such a novolac phenol resin can be obtained from a phenol compound and a crosslinking agent. Examples of the phenol compound include phenol, cresol, xylenol, butylphenol, amylphenol, nonylphenol, butylmethylphenol, trimethylphenol and phenylphenol, and examples of the naphthol compound include 1-naphthol and 2-naphthol, and further include bisphenol compounds each listed as the phenol resin-based curing agent, as others. Examples of the aldehyde compound as the crosslinking agent include formaldehyde, acetaldehyde, propylaldehyde, butylaldehyde, valeraldehyde, capronaldehyde, benzaldehyde, chloroaldehyde, bromaldehyde, glyoxal, malonaldehyde, succinaldehyde, glutaraldehyde, adipinaldehyde, pimelinaldehyde, sebacinaldehyde, acrolein, crotonaldehyde, salicylaldehyde, phthalaldehyde and hydroxybenzaldehyde. Examples of the biphenyl-based crosslinking agent include bis(methylol)biphenyl, bis(methoxymethyl)biphenyl, bis(ethoxymethyl)biphenyl and bis(chloromethyl)biphenyl.

Specific examples of the acid anhydride-based curing agent include maleic anhydride, methyltetrahydrophthalic anhydride, hexahydrophthalic anhydride, 4-methylhexahydrophthalic anhydride, methylbicyclo[2.2.1]heptane-2,3-dicarboxylic anhydride, bicyclo[2.2.1]heptane-2,3-dicarboxylic anhydride, 1,2,3,6-tetrahydrophthalic anhydride, pyromellitic anhydride, phthalic anhydride, trimellitic anhydride, methylnadic acid, copolymerized products of styrene monomers and maleic anhydrides, and copolymerized products of indene compounds and maleic anhydrides.

Specific examples of the amine-based curing agent include amine-based compounds, for example, aromatic amine compounds such as diethylenetriamine, triethylenetetramine, m-xylenediamine, isophoronediamine, diaminodiphenylmethane, diaminodiphenylsulfone, diaminodiphenyl ether, benzyldimethylamine, 2,4,6-tris(dimethylaminomethyl)phenol, polyetheramine, biguanide compounds, dicyandiamide and anisidine, and polyamideamines as condensates of acid compounds such as dimer acids with polyamine compounds.

The cyanate ester compound is not particularly limited as long as it is a compound having two or more cyanate groups (cyanic acid ester groups) in one molecule. Examples include novolac-type cyanate ester-based curing agents such as phenol novolac-type and alkylphenol novolac-type curing agents, naphthol aralkyl-type cyanate ester-based curing agents, biphenylalkyl-type cyanate ester-based curing agents, dicyclopentadiene-type cyanate ester-based curing agents, bisphenol-type cyanate ester-based curing agents such as bisphenol A-type, bisphenol F-type, bisphenol E-type, tetramethyl bisphenol F-type and bisphenol S-type curing agents, and prepolymers obtained by partial triazination of such curing agents. Specific examples of such cyanate ester-based curing agents include bifunctional cyanate resins such as bisphenol A dicyanate, polyphenol cyanate (oligo(3-methylene-1,5-phenylenecyanate), bis(3-methyl-4-cyanatephenyl)methane, bis(3-ethyl-4-cyanatephenyl)methane, bis(4-cyanatephenyl)-1,1-ethane, 4,4-dicyanate-diphenyl, 2,2-bis(4-cyanatephenyl)-1,1,1,3,3,3-hexafluoropropane, 4,4′-methylenebis(2,6-dimethylphenylcyanate), 4,4′-ethylidenediphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thio ether and bis(4-cyanatephenyl)ether, cyanic acid esters of trihydric phenols, such as tris(4-cyanatephenyl)-1,1,1-ethane and bis(3,5-dimethyl-4-cyanatephenyl)-4-cyanatephenyl-1,1,1-ethane, polyfunctional cyanate resins derived from phenol resins respectively having phenol novolac, cresol novolac, and dicyclopentadiene structures, and prepolymers obtained by partial triazination of such cyanate resins. These can be used singly or in combinations of two or more kinds thereof.

The active ester-based curing agent here used, but not particularly limited, is generally preferably a compound having two or more ester groups high in reaction activity in one molecule, such as a phenol ester compound, a thiophenol ester compound, an N-hydroxyamine ester compound, or an ester compound of a heterocyclic hydroxy compound. The active ester-based curing agent is preferably obtained by a condensation reaction of a carboxylic acid compound and/or a thiocarboxylic acid compound with a hydroxy compound and/or a thiol compound. The curing agent is preferably an active ester-based curing agent obtained from a carboxylic acid compound and a hydroxy compound, more preferably an active ester-based curing agent obtained from a carboxylic acid compound and a phenol compound and/or a naphthol compound, particularly from the viewpoint of an enhancement in heat resistance. Examples of the carboxylic acid compound include benzoic acid, acetic acid, succinic acid, maleic acid, itaconic acid, phthalic acid, isophthalic acid, terephthalic acid and pyromellitic acid. Examples of the phenol compound or the naphthol compound include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, dicyclopentadienyl diphenol, a dicyclopentadiene phenol resin as a precursor of the epoxy resin of the present invention, and phenol novolac. Such active ester-based curing agents can be used singly or in combinations of two or more kinds thereof. The active ester-based curing agent is, specifically, preferably an active ester-based curing agent including a dicyclopentadienyl diphenol structure, an active ester-based curing agent including a naphthalene structure, an active ester-based curing agent as an acetylated product of phenol novolac, or an active ester-based curing agent as a benzoylated product of phenol novolac, in particular, more preferably an active ester-based curing agent including a dicyclopentadienyl diphenol structure, including a precursor of the epoxy resin of the present invention, from the viewpoint of an excellent enhancement in peel strength.

Specific examples of other curing agents include phosphine compounds such as triphenylphosphine, phosphonium salts such as tetraphenylphosphonium bromide, imidazole compounds such as 2-methylimidazole, 2-phenylimidazole, 2-ethyl-4-methylimidazole, 2-undecylimidazole and 1-cyanoethyl-2-methylimidazole, imidazole salt compounds as salts of imidazole compounds with trimellitic acid, isocyanuric acid or boron, quaternary ammonium salts such as trimethylammonium chloride, diazabicyclo compounds, salt compounds of diazabicyclo compounds with phenol compounds or phenol novolac resin compounds, complex compounds of boron trifluoride with amine compounds or ether compounds, aromatic phosphonium or iodonium salts.

A curing accelerator can be, if necessary, used in the epoxy resin composition. Examples of the curing accelerator that can be used include imidazole compounds such as 2-methylimidazole, 2-ethylimidazole and 2-ethyl-4-methylimidazole, tertiary amine compounds such as 4-dimethylaminopyridine, 2-(dimethylaminomethyl)phenol and 1,8-diaza-bicyclo(5,4,0)undecene-7, phosphine compounds such as triphenylphosphine, tricyclohexylphosphine and triphenylphosphine triphenylborane, and metal compounds such as tin octylate. When such a curing accelerator is used, the amount of use thereof is preferably 0.02 to 5 parts by mass based on 100 parts by mass of the epoxy resin component in the epoxy resin composition of the present invention. Such a curing accelerator can be used to thereby decrease the curing temperature and shorten the curing time.

An organic solvent or a reactive diluent for viscosity adjustment can be used in the epoxy resin composition.

Examples of the organic solvent include amide compounds such as N,N-dimethylformamide and N,N-dimethylacetamide, ether compounds such as ethylene glycol monomethyl ether, dimethoxydiethylene glycol, ethylene glycol diethyl ether, diethylene glycol diethyl ether and triethylene glycol dimethyl ether, ketone compounds such as acetone, methyl ethyl ketone, methyl isobutyl ketone and cyclohexanone, alcohol compounds such as methanol, ethanol, 1-methoxy-2-propanol, 2-ethyl-1-hexanol, benzyl alcohol, ethylene glycol, propylene glycol, butyl diglycol and pine oil, acetate compounds such as butyl acetate, methoxybutyl acetate, methyl cellosolve acetate, cellosolve acetate, ethyl diglycol acetate, propylene glycol monomethyl ether acetate, carbitol acetate and benzyl alcohol acetate, benzoate compounds such as methyl benzoate and ethyl benzoate, cellosolve compounds such as methyl cellosolve, cellosolve and butyl cellosolve, carbitol compounds such as methylcarbitol, carbitol and butylcarbitol, aromatic hydrocarbon compounds such as benzene, toluene and xylene, dimethylsulfoxide, acetonitrile, and N-methylpyrrolidone, but not limited thereto.

Examples of the reactive diluent include monofunctional glycidyl ether compounds such as allyl glycidyl ether, butyl glycidyl ether, 2-ethylhexyl glycidyl ether, phenyl glycidyl ether and tolyl glycidyl ether, and monofunctional glycidyl ester compounds such as neodecanoic acid glycidyl ester, but not limited thereto.

Such organic solvents or reactive diluents are preferably used singly or as a mixture of a plurality of kinds thereof in a non-volatile content of 90% by mass or less in the resin composition, and the proper types and amounts of use thereof are appropriately selected depending on applications. For example, a polar solvent having a boiling point of 160° C. or less, such as methyl ethyl ketone, acetone or 1-methoxy-2-propanol is preferable in a printed-wiring board application, and the amount of use thereof in the resin composition, in terms of non-volatile content, is preferably 40 to 80% by mass. For example, a ketone compound, an acetate compound, a carbitol compound, an aromatic hydrocarbon compound, dimethylformamide, dimethylacetamide or N-methylpyrrolidone is preferably used in an adhesion film application, and the amount of use thereof, in terms of non-volatile content, is preferably 30 to 60% by mass.

Any other thermosetting resin or thermoplastic resin may be compounded in the epoxy resin composition as long as no characteristics are impaired. Examples include reactive functional group-containing alkylene resins such as a phenol resin, a benzoxazine resin, a bismaleimide resin, a bismaleimide triazine resin, an acrylic resin, a petroleum resin, an indene resin, a coumarone-indene resin, a phenoxy resin, a polyurethane resin, a polyester resin, a polyamide resin, a polyimide resin, a polyamideimide resin, a polyetherimide resin, a polyphenylene ether resin, a modified polyphenylene ether resin, a polyethersulfone resin, a polysulfone resin, a polyether ether ketone resin, a polyphenylenesulfide resin, a polyvinyl formal resin, a polysiloxane compound and hydroxy group-containing polybutadiene, but not limited thereto.

Various known flame retardants can be each used in the epoxy resin composition, for the purpose of an enhancement in flame retardance of a cured product obtained. Examples of such a usable flame retardant include a halogen-based flame retardant, a phosphorus-based flame retardant, a nitrogen-based flame retardant, a silicone-based flame retardant, an inorganic flame retardant and an organic metal salt-based flame retardant. A halogen-free flame retardant is preferable and a phosphorus-based flame retardant is particularly preferable, from the viewpoint of the environment. Such flame retardants may be used singly or in combinations of two or more kinds thereof.

The phosphorus-based flame retardant here used can be any of an inorganic phosphorus-based compound and an organic phosphorus-based compound. Examples of the inorganic phosphorus-based compound include red phosphorus, ammonium phosphate compounds such as monoammonium phosphate, diammonium phosphate, triammonium phosphate and ammonium polyphosphate, and inorganic nitrogen-containing phosphorus compounds such as phosphoric amide. Examples of the organic phosphorus-based compound include aliphatic phosphate, a phosphate compound, a condensed phosphate compound such as PX-200 (manufactured by Daihachi Chemical Industry Co., Ltd.), phosphazene, a phosphonic acid compound, a phosphinic acid compound, a phosphine oxide compound, a phosphorane compound, a universal organic phosphorus-based compound such as an organic nitrogen-containing phosphorus compound, and a metal salt of phosphinic acid, as well as a cyclic organic phosphorus compound such as 9,10-dihydro-9-oxa-10-phosphaphenanthrene-10-oxide, 10-(2,5-dihydrooxyphenyl)-10H-9-oxa-10-phosphaphenanthrene-10-oxide and 10-(2,7-dihydrooxynaphthyl)-10H-9-oxa-10-phosphaphenanthrene-10-oxide, and a phosphorus-containing epoxy resin and a phosphorus-containing curing agent which are derivatives each obtained by a reaction of such a phosphorus compound with a compound such as an epoxy resin or a phenol resin.

The amount of compounding of the flame retardant is appropriately selected depending on the type of the phosphorus-based flame retardant, each component of the epoxy resin composition, and the desired degree of flame retardance. For example, the phosphorus content in the organic component (except for the organic solvent) in the epoxy resin composition is preferably 0.2 to 4% by mass, more preferably 0.4 to 3.5% by mass, further preferably 0.6 to 3% by mass. A low phosphorus content may make it difficult to ensure flame retardance, and a too high phosphorus content may have an adverse effect on heat resistance. When the phosphorus-based flame retardant is used, a flame retardant aid such as magnesium hydroxide may be used in combination.

A filler can be, if necessary, used in the epoxy resin composition. Specific examples include molten silica, crystalline silica, alumina, silicon nitride, aluminum hydroxide, boehmite, magnesium hydroxide, talc, mica, calcium carbonate, calcium silicate, calcium hydroxide, magnesium carbonate, barium carbonate, barium sulfate, boron nitride, carbon, a carbon fiber, a glass fiber, an alumina fiber, a silica/alumina fiber, a silicon carbide fiber, a polyester fiber, a cellulose fiber, an aramid fiber, a ceramic fiber, fine particle rubber, silicone rubber, a thermoplastic elastomer, carbon black and a pigment. Examples of the reason for use of the filler generally include the effect of an enhancement in impact resistance. When a metal hydroxide such as aluminum hydroxide, boehmite or magnesium hydroxide is used, it has the effect of acting as a flame retardant aid and enhancing flame retardance. The amount of compounding of such a filler is preferably 1 to 150% by mass, more preferably 10 to 70% by mass based on the entire of the epoxy resin composition. A large amount of compounding may cause deterioration in adhesiveness necessary for a laminated board application and furthermore may result in a brittle cured product and impart no sufficient mechanical properties. A small amount of compounding is liable not to have any effect by compounding of a filler, for example, an enhancement in impact resistance of a cured product.

When the epoxy resin composition is formed into a plate substrate or the like, a filler here used is preferably, for example, fibrous in terms of dimension stability and bending strength, and, for example, a glass fiber substrate where a glass fiber is woven in a net-like manner is more preferable.

Into the epoxy resin composition, various additives such as a silane coupling agent, an antioxidant, a release agent, a defoamer, an emulsifier, a thixotropy imparting agent, a lubricating agent, a flame retardant and a pigment can be further compounded, if necessary. The amount of compounding of such an additive is preferably in the range of 0.01 to 20% by mass relative to the epoxy resin composition.

A fibrous base material can be impregnated with the epoxy resin composition, to thereby produce a prepreg for use in a printed-wiring board or the like. The fibrous base material here used can be, for example, a woven fabric or a non-woven fabric of an inorganic fiber such as glass, or an organic fiber such as a polyester resin, a polyamine resin, a polyacrylic resin, a polyimide resin or an aromatic polyamide resin, but not limited thereto. The method for producing the prepreg from the epoxy resin composition is not particularly limited, and the prepreg is obtained by, for example, immersion in and impregnation with a resin varnish made by adjustment of the viscosity of the epoxy resin composition by an organic solvent, and then heating and drying for semi-curing (B-staging) of a resin component, and, for example, such heating and drying can be made at 100 to 200° C. for 1 to 40 minutes. The amount of the resin in the prepreg, in terms of resin content, is preferably 30 to 80% by mass.

The curing of the prepreg can be made by a method for curing a laminated board, generally used in production of a printed-wiring board, but not limited thereto. For example, when a laminated board is formed using the prepreg, one or more of the prepregs is/are laminated, metal foil is placed on one of or both sides of the prepregs to thereby form a laminated product, and the laminated product is heated and pressurized for lamination and integration. The metal foil here used can be any foil of a single metal, an alloy, and a composite, such as copper, aluminum, brass, and nickel. The laminated product made is then pressurized and heated to thereby cure the prepregs, and thus a laminated board can be obtained. Preferably, the heating temperature is 160 to 220° C., the pressure applied is 5 to 50 MPa, and the heating and pressurizing time is 40 to 240 minutes, and thus an objective cured product can be obtained. A low heating temperature may cause progression of no sufficient curing reaction, and a high heating temperature may cause the start of pyrolysis of the epoxy resin composition. A low pressure applied may cause bubbles to remain in such a laminated board to result in deterioration in electric characteristics, and a high pressure applied may cause resin flowing before curing, not providing a laminated board having a desired thickness. Furthermore, a short heating and pressurizing time is not preferable because it may cause progression of no sufficient curing reaction, and a long heating and pressurizing time is not preferable because it may cause pyrolysis of the epoxy resin composition in the prepregs.

The epoxy resin composition can be cured by the same method as in a known epoxy resin composition, to obtain an epoxy resin-cured product. The method for obtaining the cured product can be the same method as in a known epoxy resin composition, and a method suitably used is, for example, a method for obtaining a laminated board by, for example, cast molding, injection, potting, dipping, drip coating, transfer molding or compression molding, or lamination of a form of, for example, a resin sheet, copper foil provided with a resin, or prepreg, and then curing with heating and pressurizing. The curing temperature is usually 100 to 300° C., and the curing time is usually about 1 hour to 5 hours.

The epoxy resin-cured product of the present invention can be in the form of, for example, a laminated product, a shaped product, an adhesion product, a coating film, or a film.

The epoxy resin composition is produced, and heated and cured, and a laminated board and a cured product are evaluated, and as a result, an epoxy-curable resin composition exhibiting excellent low-dielectric properties in the cured product can be provided. As dielectric properties, specifically, a relative permittivity of 3.00 or less, more preferably 2.90 or less, and a dielectric tangent of 0.015 or less, more preferably 0.010 or less can be exhibited. The glass transition temperature (Tg) of the cured product is 120° C. or more, and can be 150° C. or more.

### EXAMPLES

The present invention is specifically described with reference to Examples and Comparative Examples, but the present invention is not limited thereto. Unless particularly noted, “parts” represents “parts by mass”, “%” represents “% by mass”, and “ppm” represents “ppm by mass”. Measurement methods were respectively the following measurement methods.

Hydroxyl equivalent: measured in accordance with JIS K 0070 standard, where the unit was expressed by “g/eq.”. Unless particularly noted, the hydroxyl equivalent of a phenol resin means the phenolic hydroxyl equivalent.

Softening point: measured in accordance with a ring-and-ball method in JIS K 7234 standard. Specifically, an automatic softening point apparatus (ASP-MG4 manufactured by Meitech Company, Ltd.) was used.

Epoxy Equivalent:

The epoxy equivalent was measured in accordance with JIS K 7236 standard, where the unit was expressed by “g/eq.”. Specifically, an automatic potentiometric titrator (COM-1600ST manufactured by Hiranuma Sangyo Co., Ltd.) was used, chloroform was used as a solvent, a tetraethylammonium bromide-acetic acid solution was added, and titration with a 0.1 mol/L perchloric acid-acetic acid solution was made.

Total Content of Chlorine:

The total content of chlorine was measured in accordance with JIS K 7243-3 standard, where the unit was expressed by “ppm”. Specifically, diethylene glycol monobutyl ether was used as a solvent, a 1 mol/L potassium hydroxide-1,2-propane diol solution was added and heat-treated, and thereafter titration with a 0.01 mol/L silver nitrate solution was made with an automatic potentiometric titrator (COM-1700 manufactured by Hiranuma Sangyo Co., Ltd.).

Melt Viscosity:

The melt viscosity at 150° C. was measured with an ICI viscometer (CV-1S manufactured by Toa Industries, Ltd.).

Relative permittivity and dielectric tangent: measured in accordance with IPC-TM-650 2.5.5.9. Specifically, evaluation was made by drying a specimen in an oven set at 105° C., for 2 hours, cooling the specimen in a desiccator, and thereafter determining the relative permittivity and the dielectric tangent at a frequency of 1 GHz by a capacitance method by use of a material analyzer manufactured by AGILENT Technologies.

Copper foil peel strength and interlayer adhesion force: measured in accordance with JIS C 6481. The interlayer adhesion force was measured by pulling and peeling between the seventh layer and the eighth layer.

GPC (gel permeation chromatography) measurement: columns (TSKgelG4000H_{XL}, TSKgelG3000H_{XL} and TSKgelG2000H_{XL} manufactured by Tosoh Corporation) connected to the main body (HLC-8220 GPC manufactured by Tosoh Corporation) in series were used, and the column temperature was 40° C. The eluent here used was tetrahydrofuran (THF) at a flow rate of 1 mL/min, and the detector here used was a differential refractive index detector. The measurement specimen here used was 50 μL of one obtained by dissolving 0.1 g of a sample in 10 mL of THF and filtering the solution by a micro filter. GPC-8020 Model II version 6.00 manufactured by Tosoh Corporation was used for data processing.

ESI-MS: mass analysis was performed by subjecting a sample dissolved in acetonitrile to measurement with a mass spectrometer (LCMS-2020 manufactured by Shimadzu Corporation) by use of acetonitrile and water in a mobile phase.

Abbreviations used in Examples and Comparative Examples are as follows.

[Epoxy Resin]
E1: Epoxy resin obtained in Example 6
E2: Epoxy resin obtained in Example 7
E3: Epoxy resin obtained in Example 8
E4: Epoxy resin obtained in Example 9
E5: Epoxy resin obtained in Example 10
EH1: Epoxy resin obtained in Synthesis Example 4
EH2: Phenol-dicyclopentadiene-type epoxy resin (HP-7200H manufactured by DIC Corporation, epoxy equivalent 280, softening point 83° C., melt viscosity at 150° C., 0.40 Pa·s)

[Curing Agent]
P1: Phenol resin obtained in Example 1
P2: Phenol resin obtained in Example 2
P3: Phenol resin obtained in Example 3
P4: Phenol resin obtained in Example 4
P5: Phenol resin obtained in Example 5
PH1: Phenol resin obtained in Synthesis Example 1
PH2: Phenol resin obtained in Synthesis Example 2
PH3: Aromatic-modified phenol resin obtained in Synthesis Example 3
PH4: Phenol novolac resin (Shonol BRG-557 manufactured by Aica Kogyo Co., Ltd., hydroxyl group equivalent 105, softening point 80° C., melt viscosity at 150° C., 0.30 Pa·s)

[Curing Accelerator]

C1: 2E4MZ: 2-ethyl-4-methylimidazole (Curezol 2E4MZ manufactured by Shikoku Chemicals Corporation)

### Synthesis Example 1

A reaction apparatus including a separable flask made of glass, equipped with a stirrer, a thermometer, a nitrogen blowing tube, a dropping funnel and a cooling tube was loaded with 500 parts of 2,6-xylenol and 7.3 parts of a 47% BF₃ ether complex, and the resulting mixture was warmed to 100° C. with stirring. While this temperature was kept, 67.6 parts of dicyclopentadiene (0.12-fold moles relative to 2,6-xylenol) was dropped for 1 hour. Furthermore, the reaction was made at a temperature of 115 to 125° C. for 4 hours, and 11 parts of calcium hydroxide was added. Furthermore, 19 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 1320 parts of MIBK, and washed with water by addition of 400 parts of warm water at 80° C., and an aqueous layer as the lower layer was separated and removed. Thereafter, MIBK was evaporated and removed by warming to 160° C. under a reduced pressure of 5 mmHg, and thus 164 parts of red-brown phenol resin (PH1) was obtained. The hydroxyl group equivalent was 195 and the softening point was 73° C. In GPC, the Mw was 470, the Mn was 440, the content of an m=0 form was 2.8% by area, the content of an m=1 form was 86.2% by area, and the content of an m≥2 form was 11.0% by area. The melt viscosity at 150° C. was 0.05 Pa·s.

### Synthesis Example 2

The same reaction apparatus as in Synthesis Example 1 was loaded with 361 parts of ortho-cresol and 5.9 parts of a 47% BF₃ ether complex, and the resulting mixture was warmed to 100° C. with stirring. While this temperature was kept, 55.2 parts of dicyclopentadiene (0.13-fold moles relative to ortho-cresol) was dropped for 1 hour. Furthermore, the reaction was made at a temperature of 115 to 125° C. for 4 hours, and 9 parts of calcium hydroxide was added. Furthermore, 16 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 970 parts of MIBK, and washed with water by addition of 290 parts of warm water at 80° C., and an aqueous layer as the lower layer was separated and removed. Thereafter, MIBK was evaporated and removed by warming to 160° C. under a reduced pressure of 5 mmHg, and thus 137 parts of red-brown phenol resin (PH2) was obtained. The hydroxyl group equivalent was 184 and the softening point was 78° C. In GPC, the Mw was 460, the Mn was 410, the content of an m=0 form was 0.8% by area, the content of an m=1 form was 75.5% by area, and the content of an m≥2 form was 23.7% by area. The melt viscosity at 150° C. was 0.07 Pa·s.

### Synthesis Example 3

The same reaction apparatus as in Synthesis Example 1 was loaded with 105 parts of a phenol novolac resin (hydroxyl group equivalent 105, softening point 130° C.) and 0.1 parts of p-toluenesulfonic acid, and the temperature was raised to 150° C. While this temperature was maintained, 94 parts of styrene was dropped for 3 hours, and furthermore stirring was continued at this temperature for 1 hour. Thereafter, the resultant was dissolved in 500 parts of MIBK, and washed with water at 80° C. five times. Subsequently, MIBK was distilled off under reduced pressure, and thus aromatic modified phenol novolac resin (PH3) was obtained. The hydroxyl group equivalent was 199 and the softening point was 110° C. The melt viscosity at 150° C. was 0.18 Pa·s.

### Example 1

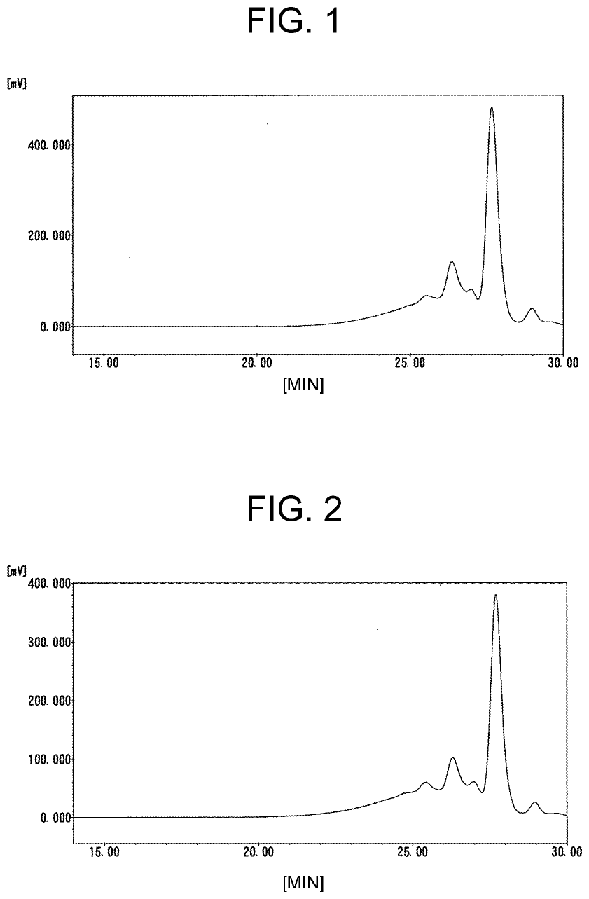

The same reaction apparatus as in Synthesis Example 1 was loaded with 100 parts of phenol resin (PH1) obtained in Synthesis Example 1, 1.0 part of para-toluenesulfonic acid-monohydrate, and 25 parts of MIBK, and the resulting mixture was warmed to 120° C. with stirring. While this temperature was kept, 30 parts of divinylbenzene (manufactured by Sigma-Aldrich Co. LLC, divinylbenzene 55%, ethylvinylbenzene 45%) (0.45-fold moles relative to phenol resin) was dropped for 1 hour. Furthermore, the reaction was made at a temperature of 120 to 130° C. for 4 hours. A product was dissolved by addition of 280 parts of MIBK, neutralized with 1.3 parts of sodium hydrogen carbonate, and washed with water by addition of 90 parts of warm water at 80° C., and an aqueous layer as the lower layer was separated and removed. Thereafter, MIBK was evaporated and removed by warming to 180° C. under a reduced pressure of 5 mmHg, and thus 123 parts of red-brown phenol resin (P1) was obtained. The hydroxyl group equivalent was 250 and the softening point was 81° C. A mass spectrum by ESI-MS (negative) was measured, and the following was confirmed: M−=375, 507, 629, 639, 761. A GPC chart of phenol resin (P1) obtained is illustrated in FIG. 1. In GPC, the Mw was 740, the Mn was 540, the content of an n=0 form was 4.9% by area, the content of an n=1 form was 53.3% by area, and the content of an n≥2 form was 41.8% by area. The melt viscosity at 150° C. was 0.13 Pa·s.

### Example 2

The same reaction apparatus as in Synthesis Example 1 was loaded with 100 parts of phenol resin (PH1) obtained in Synthesis Example 1, 1.0 part of para-toluenesulfonic acid-monohydrate, and 25 parts of MIBK, and the resulting mixture was warmed to 120° C. with stirring. While this temperature was kept, 45 parts of divinylbenzene (manufactured by Sigma-Aldrich Co. LLC, divinylbenzene 55%, ethylvinylbenzene 45%) (0.67-fold moles relative to phenol resin) was dropped for 1 hour. Furthermore, the reaction was made at a temperature of 120 to 130° C. for 4 hours. A product was dissolved by addition of 310 parts of MIBK, neutralized with 1.3 parts of sodium hydrogen carbonate, and washed with water by addition of 100 parts of warm water at 80° C., and an aqueous layer as the lower layer was separated and removed. Thereafter, MIBK was evaporated and removed by warming to 180° C. under a reduced pressure of 5 mmHg, and thus 139 parts of red-brown phenol resin (P2) was obtained. The hydroxyl group equivalent was 276 and the softening point was 71° C. A mass spectrum by ESI-MS (negative) was measured, and the following was confirmed: M−=375, 507, 629, 639, 761. In GPC, the Mw was 800, the Mn was 540, the content of an n=0 form was 6.5% by area, the content of an n=1 form was 51.1% by area, and the content of an n≥2 form was 42.4% by area. The melt viscosity at 150° C. was 0.09 Pa·s.

### Example 3

The same reaction apparatus as in Synthesis Example 1 was loaded with 80 parts of phenol resin (PH1) obtained in Synthesis Example 1, 0.8 parts of para-toluenesulfonic acid-monohydrate, and 20 parts of MIBK, and the resulting mixture was warmed to 120° C. with stirring. While this temperature was kept, 48 parts of divinylbenzene (manufactured by Sigma-Aldrich Co. LLC, divinylbenzene 55%, ethylvinylbenzene 45%) (0.90-fold moles relative to phenol resin) was dropped for 1 hour. Furthermore, the reaction was made at a temperature of 120 to 130° C. for 4 hours. A product was dissolved by addition of 280 parts of MIBK, neutralized with 1.1 parts of sodium hydrogen carbonate, and washed with water by addition of 90 parts of warm water at 80° C., and an aqueous layer as the lower layer was separated and removed. Thereafter, MIBK was evaporated and removed by warming to 180° C. under a reduced pressure of 5 mmHg, and thus 120 parts of red-brown phenol resin (P3) was obtained. The hydroxyl group equivalent was 306 and the softening point was 68° C. A mass spectrum by ESI-MS (negative) was measured, and the following was confirmed: M−=375, 507, 629, 639, 761. In GPC, the Mw was 910, the Mn was 550, the content of an n=0 form was 7.5% by area, the content of an n=1 form was 48.9% by area, and the content of an n≥2 form was 43.6% by area. The melt viscosity at 150° C. was 0.08 Pa·s.

### Example 4

The same reaction apparatus as in Synthesis Example 1 was loaded with 93 parts of phenol resin (PH1) obtained in Synthesis Example 1, 0.9 parts of para-toluenesulfonic acid-monohydrate, and 23 parts of MIBK, and the resulting mixture was warmed to 120° C. with stirring. While this temperature was kept, 41.8 parts of divinylbenzene (manufactured by Sigma-Aldrich Co. LLC, divinylbenzene 80%, ethylvinylbenzene 20%) (0.90-fold moles relative to phenol resin) was dropped for 1 hour. Furthermore, the reaction was made at a temperature of 120 to 130° C. for 4 hours. A product was dissolved by addition of 290 parts of MIBK, neutralized with 1.2 parts of sodium hydrogen carbonate, and washed with water by addition of 90 parts of warm water at 80° C., and an aqueous layer as the lower layer was separated and removed. Thereafter, MIBK was evaporated and removed by warming to 180° C. under a reduced pressure of 5 mmHg, and thus 128 parts of red-brown phenol resin (P4) was obtained. The hydroxyl group equivalent was 281 and the softening point was 88° C. A mass spectrum by ESI-MS (negative) was measured, and the following was confirmed: M−=375, 507, 629, 639, 761. In GPC, the Mw was 1400, the Mn was 650, the content of an n=0 form was 3.1% by area, the content of an n=1 form was 43.3% by area, and the content of an n≥2 form was 53.6% by area. The melt viscosity at 150° C. was 0.33 Pa·s.

### Example 5

The same reaction apparatus as in Synthesis Example 1 was loaded with 100 parts of phenol resin (PH2) obtained in Synthesis Example 2, 1.0 part of para-toluenesulfonic acid-monohydrate, and 25 parts of MIBK, and the resulting mixture was warmed to 120° C. with stirring. While this temperature was kept, 45 parts of divinylbenzene (manufactured by Sigma-Aldrich Co. LLC, divinylbenzene 55%, ethylvinylbenzene 45%) (0.45-fold moles relative to phenol resin) was dropped for 1 hour. Furthermore, the reaction was made at a temperature of 120 to 130° C. for 4 hours. A product was dissolved by addition of 310 parts of MIBK, neutralized with 1.3 parts of sodium hydrogen carbonate, and washed with water by addition of 100 parts of warm water at 80° C., and an aqueous layer as the lower layer was separated and removed. Thereafter, MIBK was evaporated and removed by warming to 180° C. under a reduced pressure of 5 mmHg, and thus 140 parts of red-brown phenol resin (P5) was obtained. The hydroxyl group equivalent was 255 and the softening point was 77° C. A mass spectrum by ESI-MS (negative) was measured, and the following was confirmed: M−=347, 479, 587, 611, 719. In GPC, the Mw was 780, the Mn was 500, the content of an n=0 form was 3.0% by area, the content of an n=1 form was 45.1% by area, and the content of an n≥2 form was 51.9% by area. The melt viscosity at 150° C. was 0.20 Pa·s.

### Example 6

To a reaction apparatus equipped with a stirrer, a thermometer, a nitrogen blowing tube, a dropping funnel and a cooling tube were added 100 parts of phenol resin (P1) obtained in Example 1, 185 parts of epichlorohydrin and 55 parts of diethylene glycol dimethyl ether, and the resulting mixture was warmed to 65° C. While the temperature was kept at 63 to 67° C. under a reduced pressure of 125 mmHg, 35.9 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 290 parts of MIBK was added to dissolve a product. Thereafter, 90 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 117 parts of red-brown epoxy resin (E1) was obtained. The resin had an epoxy equivalent of 315, a total content of chlorine of 590 ppm, and a softening point of 62° C. A GPC chart of epoxy resin (E1) obtained is illustrated in FIG. 2. In GPC, the Mw was 890, the Mn was 580, the content of a k=0 form was 3.8% by area, the content of a k=1 form was 50.7% by area, and the content of a k≥2 form was 45.5% by area. The melt viscosity at 150° C. was 0.18 Pa·s.

### Example 7

To a reaction apparatus equipped with a stirrer, a thermometer, a nitrogen blowing tube, a dropping funnel and a cooling tube were added 102 parts of phenol resin (P2) obtained in Example 2, 171 parts of epichlorohydrin and 51 parts of diethylene glycol dimethyl ether, and the resulting mixture was warmed to 65° C. While the temperature was kept at 63 to 67° C. under a reduced pressure of 125 mmHg, 33.3 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and a product was dissolved by addition of 290 parts of MIBK. Thereafter, 90 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 118 parts of red-brown epoxy resin (E2) was obtained. The resin had an epoxy equivalent of 345, a total content of chlorine of 510 ppm, and a softening point of 57° C. In GPC, the Mw was 1180, the Mn was 590, the content of a k=0 form was 5.5% by area, the content of a k=1 form was 48.0% by area, and the content of a k≥2 form was 46.5% by area. The melt viscosity at 150° C. was 0.14 Pa·s.

### Example 8

To a reaction apparatus equipped with a stirrer, a thermometer, a nitrogen blowing tube, a dropping funnel and a cooling tube were added 101 parts of phenol resin (P3) obtained in Example 3, 153 parts of epichlorohydrin and 46 parts of diethylene glycol dimethyl ether, and the resulting mixture was warmed to 65° C. While the temperature was kept at 63 to 67° C. under a reduced pressure of 125 mmHg, 29.7 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 280 parts of MIBK was added to dissolve a product. Thereafter, 80 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 113 parts of red-brown epoxy resin (E3) was obtained. The resin had an epoxy equivalent of 373 and a total content of chlorine of 530 ppm, and was semi-solid at room temperature. In GPC, the Mw was 1670, the Mn was 610, the content of a k=0 form was 6.1% by area, the content of a k=1 form was 45.5% by area, and the content of a k≥2 form was 48.4% by area. The melt viscosity at 150° C. was 0.15 Pa·s.

### Example 9

To a reaction apparatus equipped with a stirrer, a thermometer, a nitrogen blowing tube, a dropping funnel and a cooling tube were added 101 parts of phenol resin (P4) obtained in Example 4, 166 parts of epichlorohydrin and 50 parts of diethylene glycol dimethyl ether, and the resulting mixture was warmed to 65° C. While the temperature was kept at 63 to 67° C. under a reduced pressure of 125 mmHg, 32.3 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 280 parts of MIBK was added to dissolve a product. Thereafter, 90 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 118 parts of red-brown epoxy resin (E4) was obtained. The resin had an epoxy equivalent of 351, a total content of chlorine of 550 ppm, and a softening point of 77° C. In GPC, the Mw was 2080, the Mn was 690, the content of a k=0 form was 2.6% by area, the content of a k=1 form was 40.0% by area, and the content of a k≥2 form was 57.4% by area. The melt viscosity at 150° C. was 0.44 Pa·s.

### Example 10

To a reaction apparatus equipped with a stirrer, a thermometer, a nitrogen blowing tube, a dropping funnel and a cooling tube were added 100 parts of phenol resin (P5) obtained in Example 5, 181 parts of epichlorohydrin and 54 parts of diethylene glycol dimethyl ether, and the resulting mixture was warmed to 65° C. While the temperature was kept at 63 to 67° C. under a reduced pressure of 125 mmHg, 35.2 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 290 parts of MIBK was added to dissolve a product. Thereafter, 90 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 116 parts of red-brown epoxy resin (E5) was obtained. The resin had an epoxy equivalent of 323, a total content of chlorine of 580 ppm, and a softening point of 70° C. In GPC, the Mw was 1200, the Mn was 550, the content of a k=0 form was 2.5% by area, the content of a k=1 form was 42.0% by area, and the content of a k≥2 form was 55.5% by area. The melt viscosity at 150° C. was 0.32 Pa·s.

### Synthesis Example 4

To the same reaction apparatus as in Example 6 were added 150 parts of phenol resin (P1) obtained in Synthesis Example 1, 356 parts of epichlorohydrin and 107 parts of diethylene glycol dimethyl ether, and the resulting mixture was warmed to 65° C. While the temperature was kept at 63 to 67° C. under a reduced pressure of 125 mmHg, 69.1 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 450 parts of MIBK was added to dissolve a product. Thereafter, 140 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 183 parts of red-brown dicyclopentadiene-type epoxy resin (EH1) was obtained. The resin had an epoxy equivalent of 261, a total content of chlorine of 710 ppm, and a softening point of 55° C. In GPC, the Mw was 670, the Mn was 570, the content of a k=0 form was 2.3% by area, the content of a k=1 form was 73.1% by area, and the content of a k≥2 form was 24.6% by area. The melt viscosity at 150° C. was 0.10 Pa·s.

### Example 11

One hundred parts of epoxy resin (E1) as an epoxy resin, 33 parts of phenol resin (PH4) as a curing agent, and 0.40 parts of C1 as a curing accelerator were compounded, and dissolved in a mixed solvent adjusted from MEK, propylene glycol monomethyl ether and N,N-dimethylformamide, to thereby obtain an epoxy resin composition varnish. A glass cloth (WEA 7628 XS13 manufactured by Nitto Boseki Co., Ltd., 0.18 mm in thickness) was impregnated with the epoxy resin composition varnish obtained. The glass cloth impregnated was dried in a hot air oven at 150° C. for 9 minutes, to thereby obtain a prepreg. Eight of the prepregs obtained and copper foil (3EC-III manufactured by Mitsui Mining & Smelting Co., Ltd., thickness 35 μm) were stacked with the copper foil being located on and below the prepregs, and the resulting stacked product was pressed in vacuum at 2 MPa in temperature conditions of 130° C.×15 minutes+190° C.×80 minutes, to thereby obtain a laminated board having a thickness of 1.6 mm. The results of the copper foil peel strength and interlayer adhesion force of the laminated board are shown in Table 1.

The prepregs obtained were ground, to thereby provide a ground prepreg powder by passing through a 100-mesh sieve. The prepreg powder obtained was placed into a fluororesin mold, and pressed in vacuum at 2 MPa in temperature conditions of 130° C.×15 minutes+190° C.×80 minutes, to thereby obtain a test piece of 50 mm square×2 mm thickness. The results of the relative permittivity and dielectric tangent in the test piece are shown in Table 1.

### Examples 12 to 32 and Comparative Examples 1 to 8

Each laminated board and each test piece were obtained by compounding at each amount of compounding (part(s)) in Tables 1 to 4 and by the same operations performed as in Example 11. The curing accelerator was used in an amount so that the varnish gelation time could be adjusted to about 300 seconds. The same test as in Example 11 was performed. The results are shown in Tables 1 to 4.

TABLE 1

| | Example | Example | Example | Example | Example | Comparative | Comparative |
|---|---|---|---|---|---|---|---|
| | 11 | 12 | 13 | 14 | 15 | Example 1 | Example 2 |
| E1 | 100 | | | | | | |
| E2 | | 100 | | | | | |
| E3 | | | 100 | | | | |
| E4 | | | | 100 | | | |
| E5 | | | | | 100 | | |
| EH1 | | | | | | 100 | |
| EH2 | | | | | | | 100 |
| PH4 | 33 | 30 | 28 | 30 | 33 | 40 | 38 |
| C1 | 0.40 | 0.40 | 0.40 | 0.40 | 0.30 | 0.20 | 0.10 |
| Relative permittivity | 2.92 | 2.89 | 2.90 | 2.92 | 3.01 | 3.01 | 3.17 |
| Dielectric tangent | 0.013 | 0.012 | 0.011 | 0.014 | 0.014 | 0.015 | 0.021 |
| Copper foil peel strength | 1.6 | 1.4 | 1.2 | 1.5 | 1.4 | 1.7 | 1.6 |
| (kN/m) | | | | | | | |
| Interlayer adhesion | 1.3 | 1.2 | 1.0 | 1.2 | 1.2 | 1.4 | 1.2 |
| force (kN/m) | | | | | | | |

TABLE 2

| | Example | Example | Example | Example | Example | Example | Example | Example |
|---|---|---|---|---|---|---|---|---|
| | 16 | 17 | 18 | 19 | 20 | 21 | 22 | 23 |
| E2 | 100 | 100 | 100 | 100 | 100 | 100 | 100 | 100 |
| P1 | 72 | | | | | | | |
| P2 | | 80 | | | | | | |
| P3 | | | 89 | | | | | |
| P4 | | | | 81 | | | | |
| P5 | | | | | 74 | | | |
| PH1 | | | | | | 57 | | |
| PH2 | | | | | | | 53 | |
| PH3 | | | | | | | | 58 |
| C1 | 0.55 | 0.60 | 0.65 | 0.50 | 0.50 | 0.45 | 0.40 | 0.70 |
| Relative permittivity | 2.69 | 2.65 | 2.65 | 2.70 | 2.79 | 2.72 | 2.78 | 2.81 |
| Dielectric tangent | 0.009 | 0.008 | 0.007 | 0.010 | 0.010 | 0.011 | 0.013 | 0.011 |
| Copper foil peel strength (kN/m) | 1.2 | 1.1 | 1.1 | 1.3 | 1.2 | 1.5 | 1.3 | 1.2 |
| Interlayer adhesion force (kN/m) | 1.1 | 1.0 | 1.0 | 1.1 | 1.1 | 1.2 | 1.1 | 0.7 |

TABLE 3

| | Example | Example | Example | Example | Example | Comparative | Comparative | Comparative |
|---|---|---|---|---|---|---|---|---|
| | 24 | 25 | 26 | 27 | 28 | Example 3 | Example 4 | Example 5 |
| EH1 | 100 | 100 | 100 | 100 | 100 | 100 | 100 | 100 |
| P1 | 96 | | | | | | | |
| P2 | | 106 | | | | | | |
| P3 | | | 117 | | | | | |
| P4 | | | | 108 | | | | |
| P5 | | | | | 98 | | | |
| PH1 | | | | | | 75 | | |
| PH2 | | | | | | | 71 | |
| PH3 | | | | | | | | 76 |
| C1 | 0.50 | 0.50 | 0.50 | 0.50 | 0.40 | 0.40 | 0.35 | 0.52 |
| Relative permittivity | 2.85 | 2.82 | 2.81 | 2.85 | 2.88 | 2.94 | 2.97 | 2.93 |
| Dielectric tangent | 0.010 | 0.009 | 0.008 | 0.011 | 0.011 | 0.013 | 0.013 | 0.012 |
| Copper foil peel strength (kN/m) | 1.5 | 1.3 | 1.2 | 1.4 | 1.3 | 1.8 | 1.6 | 1.6 |
| Interlayer adhesion force (kN/m) | 1.3 | 1.1 | 1.0 | 1.2 | 1.2 | 1.5 | 1.4 | 0.8 |

TABLE 4

| | Example | Example | Example | Example | Comparative | Comparative | Comparative |
|---|---|---|---|---|---|---|---|
| | 29 | 30 | 31 | 32 | Example 6 | Example 7 | Example 8 |
| E2 | 100 | 100 | 100 | | | | |
| EH2 | | | | 100 | 100 | 100 | 100 |
| P2 | 40 | 40 | 40 | 99 | | | |
| PH1 | 28 | | | | 70 | | |
| PH2 | | 27 | | | | 66 | |
| PH3 | | | | | | | 71 |
| PH4 | | | 15 | | | | |
| C1 | 0.55 | 0.50 | 0.50 | 0.30 | 0.22 | 0.20 | 0.25 |
| Relative permittivity | 2.69 | 2.72 | 2.77 | 2.98 | 3.03 | 3.10 | 3.09 |
| Dielectric tangent | 0.009 | 0.011 | 0.010 | 0.014 | 0.016 | 0.018 | 0.018 |
| Copper foil peel strength (kN/m) | 1.3 | 1.2 | 1.3 | 1.2 | 1.7 | 1.5 | 1.4 |
| Interlayer adhesion force (kN/m) | 1.1 | 1.0 | 1.1 | 1.0 | 1.4 | 1.2 | 0.6 |

As is clear from the results, each of the polyvalent hydroxy resins and each of the epoxy resins obtained in Examples exhibit very favorable low-viscosity properties, and a resin composition including such each resin can provide a resin-cured product that exhibits very favorable low-dielectric properties with adhesiveness being kept at 1.0 kN/m or more causing no problems in practical use.

### INDUSTRIAL APPLICABILITY

The polyvalent hydroxy resin, the epoxy resin or the epoxy resin composition of the present invention can be utilized in paints, civil adhesion, cast molding, electrical and electronic materials, film materials, and the like, and is useful particularly in an application of a printed-wiring board as one of electrical and electronic materials.

1. A polyvalent hydroxy resin represented by the following general formula (1): 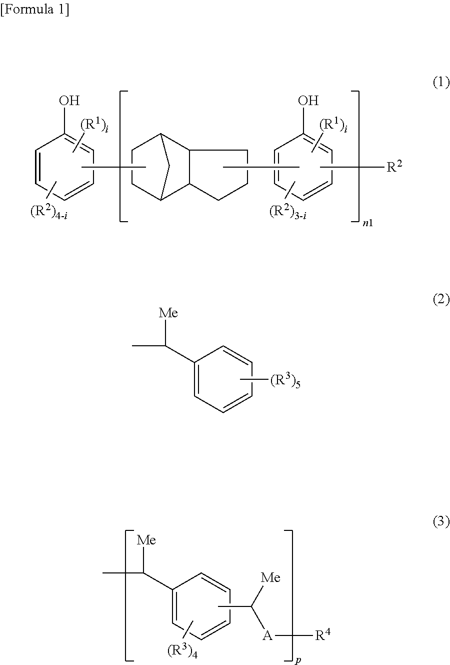
wherein each R¹ independently represents a hydrocarbon group having 1 to 8 carbon atoms, each R² independently represents a hydrogen atom, a group represented by formula (2), or a group represented by formula (3), and at least one R² is represented by formula (2) or formula (3); each R³ independently represents a hydrogen atom or a hydrocarbon group having 1 to 8 carbon atoms, and each R⁴ independently represents a hydrogen atom or a group represented by formula (2); A represents a residue obtained by removing two R² from the formula (1) and each R² here represents a hydrogen atom or a group represented by formula (2); Me represents a methyl group; i is an integer of 0 to 2; n1 represents the number of repetitions and an average value thereof is a number of 0 to 5; and p represents the number of repetitions and an average value thereof is a number of 0.01 to 3.

2. The polyvalent hydroxy resin according to claim 1, wherein R¹ is a methyl group or a phenyl group, and i is 1 or 2.

3. A method for producing a polyvalent hydroxy resin, comprising reacting a polyvalent hydroxy resin (a) represented by the following general formula (4) and an aromatic vinyl compound (b) represented by the following general formula (5a) and/or general formula (5b): 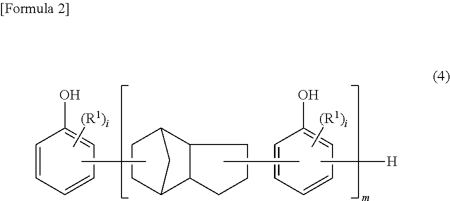
wherein each R¹ independently represents a hydrocarbon group having 1 to 8 carbon atoms; i is an integer of 0 to 2; and m represents the number of repetitions and an average value thereof is a number of 0 to 5; 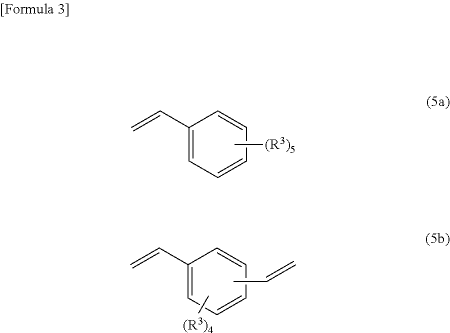
wherein each R³ represents a hydrogen atom or a hydrocarbon group having 1 to 8 carbon atoms.

4. The method for producing a polyvalent hydroxy resin according to claim 3, wherein 0.05 to 2.0 mol of the aromatic vinyl compound (b) per mol of a phenolic hydroxyl group of the polyvalent hydroxy resin (a) is reacted at a reaction temperature of 50 to 200° C. in the presence of an acid catalyst.

5. An epoxy resin represented by the following general formula (6): 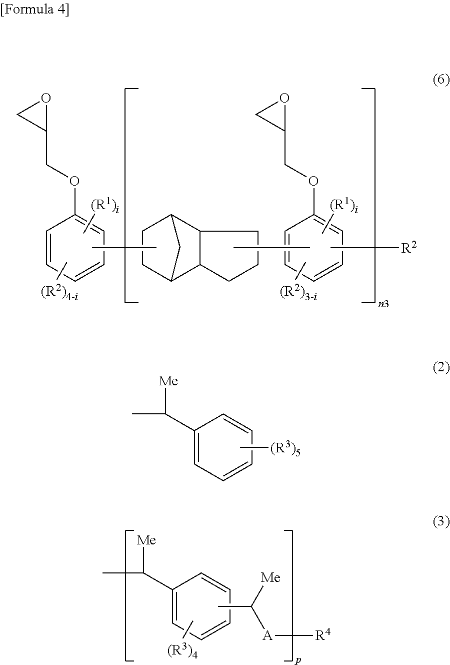
wherein each R¹ independently represents a hydrocarbon group having 1 to 8 carbon atoms, each R² independently represents a hydrogen atom, a group represented by formula (2), or a group represented by formula (3), and at least one R² is represented by formula (2) or formula (3); each R³ independently represents a hydrogen atom or a hydrocarbon group having 1 to 8 carbon atoms, and each R⁴ independently represents a hydrogen atom or a group represented by formula (2); A represents a residue obtained by removing two R² from the formula (6) and each R² here represents a hydrogen atom or a group represented by formula (2); i is an integer of 0 to 2; n3 represents the number of repetitions and an average value thereof is a number of 0 to 5; and p represents the number of repetitions and an average value thereof is a number of 0.01 to 3.

6. A method for producing an epoxy resin, comprising reacting 1 to 20 mol of epihalohydrin per mol of a phenolic hydroxyl group of the polyvalent hydroxy resin represented by the general formula (1) according to claim 1 in the presence of an alkali metal hydroxide.

7. An epoxy resin composition comprising an epoxy resin and a curing agent, wherein the epoxy resin composition essentially comprises the polyvalent hydroxy resin according to claim 1 as the curing agent.

8. A prepreg using the epoxy resin composition according to claim 7.

9. A laminated board using the epoxy resin composition according to claim 7.

10. A printed-wiring substrate using the epoxy resin composition according to claim 7.

11. A cured product obtained by curing the epoxy resin composition according to claim 7.

12. An epoxy resin composition comprising an epoxy resin and a curing agent, wherein the epoxy resin composition essentially comprises the epoxy resin according to claim 5 as the epoxy resin.

13. A prepreg using the epoxy resin composition according to claim 12.

14. A laminated board using the epoxy resin composition according to claim 12.

15. A printed-wiring substrate using the epoxy resin composition according to claim 12.

16. A cured product obtained by curing the epoxy resin composition according to claim 12.
